(19) United States
(12) Patent Application Publication
(10) Pub. No.: US 2025/0147416 A1
(43) Pub. Date: May 8, 2025

(54) PHOTORESIST COMPOSITION

(71) Applicants: POSTECH RESEARCH AND BUSINESS DEVELOPMENT FOUNDATION, Pohang-si, Gyeongsangbuk-do (KR); RESEARCH & BUSINESS FOUNDATION SUNGKYUNKWAN UNIVERSITY, Swon-si, Gyeonggi-do (KR)

(72) Inventors: Myung-Gil KIM, Seoul (KR); Chan-Cuk HWANG, Pohang-si (KR); Yeo-Kyung KANG, Seoul (KR); Dae-Sung JUNG, Pohang-si (KR)

(73) Assignees: POSTECH RESEARCH AND BUSINESS DEVELOPMENT FOUNDATION, Pohang-si, Gyeongsangbuk-do (KR); RESEARCH & BUSINESS FOUNDATION SUNGKYUNKWAN UNIVERSITY, Suwon-si, Gyeonggi-do (KR)

(21) Appl. No.: 18/835,612

(22) PCT Filed: Jan. 3, 2023
(86) PCT No.: PCT/KR2023/000098

§ 371 Date: Aug. 2, 2024

(30) Foreign Application Priority Data
Feb. 4, 2022 (KR) 10-2022-0014532

(51) Int. Cl. G03F 7/004; G03F 7/16; G03F 7/20

(52) U.S. Cl. CPC G03F 7/0042; G03F 7/0048; G03F 7/168; G03F 7/2004

(57) ABSTRACT

The present disclosure relates to a photoresist composition including a tin-oxo cluster, an oxidizing agent, and a polar organic solvent in which when irradiated with ultraviolet, bonds constituting the cluster are broken to form cross-linking between the clusters

### TECHNICAL FIELD

The present disclosure relates to a photoresist composition.

### BACKGROUND ART

In the semiconductor industry, the implementation of fine circuit patterns is attracting attention as an important industrial issue to improve the performance of devices and achieve high integration. Accordingly, various process technologies such as self-assembly, nanoimprinting, electron-beam lithography, and ultrafine lithography using transparent masks have been developed to implement patterns from several micro to sub-nano scales.

Recently, chip manufacturers have introduced next-generation light source technologies of 13.5 nm extreme ultraviolet (EUV) and 6.5 nm beyond extreme ultraviolet (BEUV) with shorter wavelengths than 193 nm-based deep ultraviolet (DUV) to achieve a technological leap toward implementing nodes of several nanometers. However, in order to perform a lithography process by introducing a high-end light source, an organic polymer-based photoresist previously used in the industry cannot be used, so that the development of an EUV photoresist is urgent.

Conventional organic polymer-based photoresists use the principle of chemically amplified resist (CAR). Therefore, the organic polymer-based photoresist is basically composed of a solvent, a high molecular weight polymer, and a photoacid generator (PAG), and when exposed to light with a wavelength of 248 nm or 193 nm, acid is generated and amplified, and the structure of the high molecular weight polymer is broken or cross-linked by the generated acid, thereby changing the solubility. Due to the change of solubility, patterns can be implemented after development. However, when applying conventional organic photoresists to EUV, there is a problem of reduced sensitivity and resolution due to a low EUV absorption coefficient. In addition, in order to implement fine patterns, a thin thickness of the photoresist is required to a certain level, but the lower the sensitivity, the more difficult it is to secure resistance to etching, which causes pattern collapse or reduced surface uniformity, thereby making industrial application impossible. In addition, there are difficulties in achieving fine patterns due to the inherent low mechanical and chemical stability of organic materials.

To solve the problems of conventional organic photoresists for EUV photoreactivity, inorganic material-based photoresists are being developed in industry and academia, and among the materials, hydrogen silsesquioxane (HSQ), which is a polysiloxane material composed of Si and O, exhibits excellent mechanical and chemical stability as an extreme ultraviolet photoresist. However, since Si and O elements belong to a group of elements with low absorption coefficients for extreme ultraviolet in addition to C, N, F, Na, Mg, Al, Cr, Mn, Fe, Co, Ni, Cu, and Zn, there is a limit to implementing high photosensitivity.

Korean Patent Registration No. 10-1799396 relates to a photoresist composition and a method for forming a pattern using the same. Korean Patent Registration No. 10-1799396 discloses a photoresist composition including an alkaline-soluble resin, a photosensitive agent including a compound including diazonaphthoquinone, and a solvent to form a photoresist pattern having a high profile angle, but does not disclose a photoresist composition including a tin-oxo cluster and an oxidizing agent.

### DISCLOSURE

### Technical Problem

The present disclosure is intended to solve the problems of the above-mentioned prior art, and an object of the present disclosure is to provide a photoresist composition having excellent mechanical and chemical stability and excellent photosensitivity.

Another object of the present disclosure is to provide a photolithography process using the photoresist composition.

Yet another object of the present disclosure is to provide an EUV photoresist including the photoresist composition.

Objects of the present disclosure are not limited to the above-mentioned objects, and other objects, which are not mentioned above, can be clearly understood by those skilled in the art from the following descriptions.

### Technical Solution

As a technical means for achieving the technical problem, a first aspect of the present disclosure provides a photoresist composition including a tin-oxo cluster; an oxidizing agent: and a polar organic solvent, in which when irradiated with ultraviolet, bonds constituting the cluster are broken to form cross-linking between the clusters.

According to an embodiment of the present disclosure, the tin-oxo cluster may include a compound represented by the following Chemical Formula 1, but is not limited thereto:

[(BuSn)₁₂O₁₄(OH)₆][X]₂ [Chemical Formula 1]
(in Chemical Formula 1, X is p-CH₃C₆H₄SO₃ or OH).

According to an embodiment of the present disclosure, the X may be substituted with a radical reaction derivative by the oxidizing agent, but is not limited thereto.

According to an embodiment of the present disclosure, the radical reaction derivative may include anions selected from the group consisting of NO₃⁻, BrO₃⁻, ClO₄⁻, IO₄⁻, and combinations thereof, but is not limited thereto.

According to an embodiment of the present disclosure, the photosensitivity of the photoresist composition may be increased by the substitution, but is not limited thereto.

According to an embodiment of the present disclosure, the oxidizing agent may include an oxidizing agent selected from the group consisting of nitric acid, bromic acid, perchloric acid, periodic acid, and combinations thereof, but is not limited thereto.

According to an embodiment of the present disclosure, the polar organic solvent may include a solvent selected from the group consisting of methanol, ethanol, 2-propanol, 2-methoxyethanol, and combinations thereof, but is not limited thereto.

A second aspect of the present disclosure provides a photolithography process including forming a thin film by coating the photoresist composition according to the first aspect of the present disclosure; heat-treating the thin film; irradiating ultraviolet after disposing a mask on the thin film: and immersing the thin film in a solvent.

According to an embodiment of the present disclosure, the bonds constituting the cluster may be broken by the irradiation to form cross-linking between the clusters, but are not limited thereto.

According to an embodiment of the present disclosure, in the immersing of the thin film in the solvent, a portion of the thin film that is not irradiated with ultraviolet may be dissolved in the solvent, but is not limited thereto.

According to an embodiment of the present disclosure, the coating may be performed by spin coating, bar coating, gravure printing, screen printing or ink-jet printing, but is not limited thereto.

According to an embodiment of the present disclosure, the heat treatment may be performed in a temperature range of 30° C. to 150° C., but is not limited thereto.

According to an embodiment of the present disclosure, the solvent may include a solvent selected from the group consisting of ethanol, isopropyl alcohol, butanol, methyl ethyl ketone, dimethyl sulfoxide, and combinations thereof, but is not limited thereto.

A third aspect of the present disclosure provides an EUV photoresist including the photoresist composition according to the first aspect of the present disclosure.

The above-mentioned technical solutions are merely exemplary and should not be construed as limiting the present disclosure. In addition to the above-described embodiments, additional embodiments may exist in the drawings and detailed description of the invention.

### Advantageous Effects

According to the embodiments of the present disclosure, the photoresist composition includes a tin-oxo cluster and an oxidizing agent, and the composition includes tin (Sn), an element exhibiting high extreme ultraviolet absorbance, in the photoresist to increase the absorption rate and sensitivity to photons to induce an efficient photo-reaction, thereby achieving high sensitivity and patterning effects even with a small amount of light.

In addition, the photoresist composition according to the present disclosure may achieve amplification of the reaction sensitivity to extreme ultraviolet compared to a cluster material without a radical reaction derivative by substituting anions present around the cluster structure with the radical reaction derivative through the oxidizing agent to increase the radical reaction efficiency even with a short exposure time.

In addition, it is possible to stably apply the photoresist composition to the process and achieve excellent pattern formation and maintenance, excellent uniformity, and high solvent selectivity during Wet Develop by selecting an organic solvent and optimizing a mixing ratio for the chemical stability of the photoresist composition introduced with the radical reaction derivative.

However, effects obtainable herein are not limited to the effects described above, and other effects may be present.

### DESCRIPTION OF DRAWINGS

FIG. 1 is a schematic diagram of synthesis of a photoresist composition according to an embodiment of the present disclosure.

FIG. 2 is a flowchart of a photoresist process according to an embodiment of the present disclosure.

FIG. 3 is a graph showing results of confirming photoreactivity according to an exposure time in photoresist compositions according to Example and Comparative Example of the present disclosure.

FIG. 4 is results of patterning photoresist compositions for each DUV exposure time according to Example and Comparative Example of the present disclosure.

FIG. 5 is a thermogravimetric analysis (TGA) result of a photoresist composition according to Example of the present disclosure.

FIG. 6 is an X-ray photoelectron spectroscopy (XPS) result of a photoresist composition before/after DUV exposure according to Example 1 of the present disclosure.

FIG. 7 is an X-ray photoelectron spectroscopy (XPS) result of a photoresist composition before/after DUV exposure according to Example 2 of the present disclosure.

FIG. 8 is an X-ray photoelectron spectroscopy (XPS) result of a photoresist composition before/after DUV exposure according to Example 3 of the present disclosure.

FIG. 9 is a micropattern formation result of a photoresist composition before/after EUV exposure according to Example 1 of the present disclosure.

### BEST MODE

Hereinafter, embodiments of the present disclosure will be described in detail so as to be easily implemented by those skilled in the art, with reference to the accompanying drawings. However, the present disclosure may be embodied in many different forms and are not limited to the embodiments to be described herein. In addition, parts not related with the description have been omitted in order to clearly describe the present disclosure in the drawings and throughout the present specification, like reference numerals designate like elements.

Further, throughout this specification, when a certain part is “connected” with the other part, it is meant that the certain part may be “directly connected” with the other part and “electrically connected” with the other part with another element interposed therebetween.

Throughout the present specification, it will be understood that when a certain member is located “on”, “above”, “at the top of”, “under”, “below”, and “at the bottom of” the other member, a certain member is in contact with the other member and another member may also be present between the two members.

Throughout the specification, a case where a part “includes” an element will be understood to imply the inclusion of stated elements but not the exclusion of any other elements unless explicitly described to the contrary.

The terms “about”, “substantially”, and the like to be used in the present specification are used as a numerical value or a value close to the numerical value when inherent manufacturing and material tolerances are presented in the stated meaning, and used to prevent an unscrupulous infringer from unfairly using disclosed contents in which precise or absolute numerical values are mentioned to help in the understanding of the present disclosure. Throughout the present specification, the term of “step to” or “step of” does not mean “step for”.

Throughout the present specification, the term “combinations thereof” included in the expression of the Markush form means one or more mixtures or combinations selected from the group consisting of components described in the expression of the Markush form, and means to include at least one selected from the group consisting of the components.

Throughout the present specification, “A and/or B” means “A or B, or A and B”.

Hereinafter, a photoresist composition and a photoresist process of the present disclosure will be specifically described with reference to embodiments, Examples, and drawings. However, the present disclosure is not limited to these embodiments, Examples and drawings.

As a technical means for achieving the technical problem, a first aspect of the present disclosure provides a photoresist composition including a tin-oxo cluster; an oxidizing agent: and a polar organic solvent, in which when irradiated with ultraviolet, bonds constituting the cluster are broken to form cross-linking between the clusters.

The photoresist composition according to the present disclosure includes a tin-oxo cluster and an oxidizing agent, and the composition includes tin (Sn), an element exhibiting high extreme ultraviolet absorbance, in the photoresist to increase the absorption rate and sensitivity to photons and thus induce an efficient photo-reaction, thereby achieving high sensitivity and patterning effects even with a small amount of light.

In addition, the photoresist composition according to the present disclosure may achieve amplification of the reaction sensitivity to extreme ultraviolet compared to a cluster material without a radical reaction derivative by substituting anions present around the cluster structure with the radical reaction derivative through the oxidizing agent to increase the radical reaction efficiency even with a short exposure time.

In addition, it is possible to stably apply the photoresist composition to the process and achieve excellent pattern formation and maintenance, excellent uniformity, and high solvent selectivity during Wet Develop by selecting an organic solvent and optimizing a mixing ratio for the chemical stability of the photoresist composition introduced with the radical reaction derivative.

In the photoresist composition according to the present disclosure, when exposed to ultraviolet, a portion exposed to light is changed to be insoluble by causing a polymerization reaction to form cross-linking with neighboring cluster units, and a portion covered by a mask maintains its properties and can be developed using a polar solvent to form a pattern, and ultimately, a strip may be formed using a more polar solvent or acid.

The ultraviolet includes 13.5 nm extreme ultraviolet (EUV) and 6.5 nm beyond extreme ultraviolet (BEUV) next-generation light sources. Unlike a conventional photoresist composition that has problems, such as low absorbance for extreme ultraviolet, unstable chemical and mechanical properties, low etching resistance, and uncontrollable photosensitivity due to a chemical amplification effect, the photoresist composition according to the present disclosure may have high absorbance for EUV and BEUV and stable chemical and mechanical properties.

According to an embodiment of the present disclosure, the tin-oxo cluster may include a compound represented by the following Chemical Formula 1, but is not limited thereto:

[(BuSn)₁₂O₁₄(OH)₆][X]₂ [Chemical Formula 1]
(in Chemical Formula 1, X is p-CH₃C₆H₄SO₃ or OH).

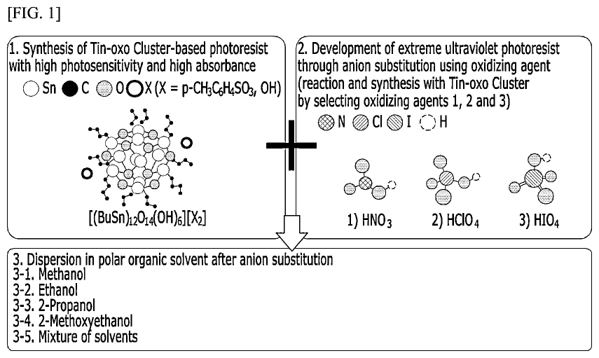

FIG. 1 is a schematic diagram of synthesis of a photoresist composition according to an embodiment of the present disclosure.

Referring to FIG. 1, the tin-oxo cluster is synthesized as a starting material for a photoresist based on Metal-oxo cluster consisting of Sn, which exhibits high extreme ultraviolet absorbance, and a Metal-oxo cage as a basic skeleton consists of Sn, C, O, and H, and it can be confirmed that a butyl group is bonded to Sn and p-CH₃C₆H₄SO₃ or a hydroxyl group exists as an anion around the cage.

According to an embodiment of the present disclosure, the X may be substituted with a radical reaction derivative by the oxidizing agent, but is not limited thereto.

According to an embodiment of the present disclosure, the photosensitivity of the photoresist composition may be increased by the substitution, but is not limited thereto.

The oxidizing agent may maximize a photoradical reaction of the photoresist composition according to the present disclosure by substituting the X, which is an anion present around the tin-oxo cluster, with a radical reaction derivative.

Referring to FIG. 1, it can be confirmed that the oxidizing agent is used to increase the radical oxidation reaction efficiency by substituting the anions around the cluster cage with a radical reaction derivative.

According to an embodiment of the present disclosure, the radical reaction derivative may include an anion selected from the group consisting of NO₃⁻, BrO₃⁻, ClO₄⁻, IO₄⁻, and combinations thereof, but is not limited thereto.

According to an embodiment of the present disclosure, the oxidizing agent may include an oxidizing agent selected from the group consisting of nitric acid, bromic acid, perchloric acid, periodic acid, and combinations thereof, but is not limited thereto.

The radical reaction derivative may vary depending on a type of oxidizing agent used. For example, when nitric acid is used as the oxidizing agent, the radical reaction derivative may be NO₃⁻, but is not limited thereto.

According to an embodiment of the present disclosure, the polar organic solvent may include a solvent selected from the group consisting of methanol, ethanol, 2-propanol, 2-methoxyethanol, and combinations thereof, but is not limited thereto.

The photoresist composition according to the present disclosure is finally formed into ink through a process of mixing the oxidizing agent that enables introduction of the radical reaction derivative with the tin-oxo cluster, introducing radical reaction derivative ions around the cluster cage, and then dispersing the ions in a polar organic solvent. At this time, it is possible to stably apply the photoresist composition to the process and achieve excellent pattern formation and maintenance, excellent uniformity, and high solvent selectivity during Wet Develop by selecting an organic solvent and optimizing a mixing ratio.

A second aspect of the present disclosure provides a photolithography process including forming a thin film by coating the photoresist composition according to the first aspect of the present disclosure; heat-treating the thin film; irradiating ultraviolet after disposing a mask on the thin film: and immersing the thin film in a solvent.

With respect to the photolithography process according to the second aspect of the present disclosure, the detailed description of parts duplicated with the first aspect of the present disclosure has been omitted, but even if the description is omitted, the contents disclosed in the first aspect of the present disclosure may be equally applied to the second aspect of the present disclosure.

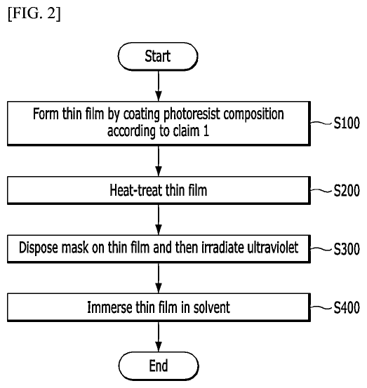

FIG. 2 is a flowchart of a photoresist process according to an embodiment of the present disclosure.

First, the photoresist composition according to the first aspect of the present disclosure is coated to form a thin film (S100).

According to an embodiment of the present disclosure, the coating may be performed by spin coating, bar coating, gravure printing, screen printing or ink-jet printing, but is not limited thereto.

The photoresist composition according to the present disclosure is formed into solvent-based ink and can be formed as a thin film on a substrate through general spin coating, bar coating, gravure printing, and screen printing. Furthermore, in the industry, the photoresist composition is applied to ink-jet printing to enable substrate printing.

Next, the thin film is heat-treated (S200).

The thin film may be heat-treated before irradiating with ultraviolet to maximize reactivity and ensure stable formation of the thin film.

According to an embodiment of the present disclosure, the heat treatment may be performed in a temperature range of 30° C. to 150° C., but is not limited thereto.

Next, the mask is disposed on the thin film and then irradiated with ultraviolet (S300).

According to an embodiment of the present disclosure, the bonds constituting the cluster may be broken by the irradiation to form cross-linking between the clusters, but are not limited thereto.

When irradiated with ultraviolet, a portion exposed to light is changed to be insoluble by causing a polymerization reaction to form cross-linking with neighboring cluster units, and a portion covered by the mask maintains solubility in a polar solvent to form patterning during Wet Develop.

Finally, the thin film is immersed in a solvent (S400).

According to an embodiment of the present disclosure, in the immersing of the thin film in the solvent, a portion of the thin film that is not irradiated with ultraviolet may be dissolved in the solvent, but is not limited thereto.

As described above, the portion that is not irradiated with ultraviolet maintains solubility in the solvent, so that when the thin film is immersed in the solvent, the portion that is not irradiated with ultraviolet is dissolved to form a pattern in the thin film.

According to an embodiment of the present disclosure, the solvent may include a solvent selected from the group consisting of ethanol, isopropyl alcohol, butanol, methyl ethyl ketone, dimethyl sulfoxide, and combinations thereof, but is not limited thereto.

A third aspect of the present disclosure provides an EUV photoresist including the photoresist composition according to the first aspect of the present disclosure.

With respect to the EUV photoresist according to the third aspect of the present disclosure, the detailed description of the duplicated parts with the first aspect and/or the second aspect of the present disclosure has been omitted, but even if the description thereof has been omitted, the contents disclosed in the first aspect and/or the second aspect of the present disclosure may be equally applied to the third aspect of the present disclosure.

In the photoresist composition according to the present disclosure, when exposed to ultraviolet, a portion exposed to light is changed to be insoluble by causing a polymerization reaction to form cross-linking with neighboring cluster units, and a portion covered by the mask maintains its properties and can be developed using a polar solvent to form a pattern, and ultimately, a strip may be formed using a more polar solvent or acid.

The ultraviolet includes 13.5 nm extreme ultraviolet (EUV) and 6.5 nm beyond extreme ultraviolet (BEUV) next-generation light sources. Unlike a conventional photoresist composition that has problems, such as low absorbance for extreme ultraviolet, unstable chemical and mechanical properties, low etching resistance, and uncontrollable photosensitivity due to a chemical amplification effect, the photoresist composition according to the present disclosure may have high absorbance for EUV and BEUV and stable chemical and mechanical properties.

The above-mentioned technical solutions are merely exemplary and should not be construed as limiting the present disclosure. In addition to the above-described embodiments, additional embodiments may exist in the drawings and detailed description of the invention.

Hereinafter, the present disclosure will be described in more detail with reference to the following Examples, but the following Examples are only for illustrative purposes and are not intended to limit the scope of the present disclosure.

### [Example 1] Preparation of Photoresist Composition ([(BuSn)₁₂O₁₄(OH)₆][NO₃]₂)

[(BuSn)₁₂O₁₄(OH)₆][OH]₂ was mixed with nitric acid to prepare a [(BuSn)₁₂O₁₄(OH)₆][NO₃]₂ photoresist, and then the photoresist was dissolved in a polar organic solvent such as methanol, ethanol, 2-propanol, or 2-methoxyethanol, or a mixed solvent to prepare a 6.1 mM photoresist composition.

### [Example 2] Preparation of Photoresist Composition ([(BuSn)₁₂O₁₄(OH)₆][ClO₄]₂)

[(BuSn)₁₂O₁₄(OH)₆][OH]₂ was mixed with perchloric acid to prepare a [(BuSn)₁₂O₁₄(OH)₆][ClO₄]₂ photoresist, and then the photoresist was dissolved in a polar organic solvent such as methanol, ethanol, 2-propanol, or 2-methoxyethanol, or a mixed solvent to prepare a 6.1 mM photoresist composition.

### [Example 3] Preparation of Photoresist Composition ([(BuSn)₁₂O₁₄(OH)₆][IO₄]₂)

[(BuSn)₁₂O₁₄(OH)₆][OH]₂ was mixed with periodic acid to prepare a [(BuSn)₁₂O₁₄(OH)₆][IO₄]₂ photoresist, and then the photoresist was dissolved in a polar organic solvent such as methanol, ethanol, 2-propanol, or 2-methoxyethanol, or a mixed solvent to prepare a 6.1 mM photoresist composition.

### Comparative Example

BuSnOOH, p-toluenesulfonic acid monohydrate, and toluene were reacted for 48 hours to prepare [(BuSn)₁₂O₁₄(OH)₆][p-CH₃C₆H₄SO₃]₂, and then the prepared compound was dissolved in a polar organic solvent such as methanol, ethanol, 2-propanol, 2-methoxyethanol, or a mixed solvent, which was used as Comparative Example.

### [Experimental Example 1] Degree of Photoreaction According to DUV Dosage

An experiment was performed to compare the degree of photoreaction according to a DUV dosage of a photoresist composition.

First, the photoresist compositions according to Examples 1 to 3 and Comparative Example were spin-coated (3000 rpm, 30 sec) on a substrate, respectively, to form a thin film, and then annealed at 90° C. for about 1 minute and irradiated with DUV.

Next, the thin film was immersed in an organic solvent, developed for 1 minute, and then the remaining thickness was confirmed and displayed in a graph.

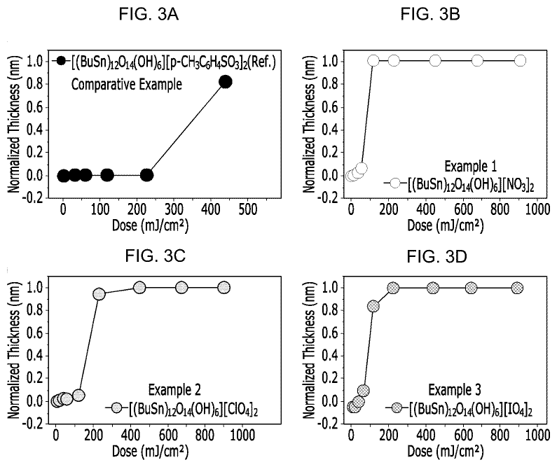

FIG. 3 is a graph showing results of confirming the photoreactivity according to an exposure time in photoresist compositions according to Examples and Comparative Example of the present disclosure.

Referring to FIG. 3, it can be confirmed that in the case of the photoresist according to Comparative Example, there is almost no photoreaction efficiency at 300 mJ/cm² or less, and the photoreaction progresses at about 80% at 440 mJ/cm².

On the other hand, it was confirmed that the photoresist according to Example 1 of at least 116 mJ/cm², the photoresist according to Example 2 of 228 mJ/cm², and the photoresist according to Example 3 of 213 mJ/cm² had 100% radical reaction during exposure, respectively, and thus it can be seen that the photoreaction efficiency was improved at most 4-fold through the introduction of the radical derivative.

### [Experimental Example 2] Patterning Result According to Exposure Time

An experiment was conducted to confirm the possibility of patterning, the stability of the implemented pattern, and the degree of surface roughness after Wet Develop by partially irradiating light through a Quartz Mask during DUV exposure on the thin films prepared using the photoresist compositions according to Examples 1 to 3 and Comparative Example.

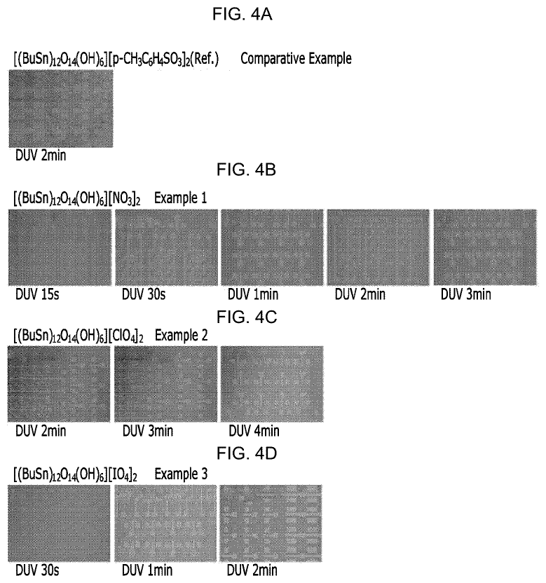

FIG. 4 is results of patterning photoresist compositions for each DUV exposure time according to Examples and Comparative Example of the present disclosure.

In Comparative Example, when DUV 2 min (440 mJ/cm²) was performed, the photoreaction did not progress sufficiently, so that the patterns collapsed and the boundaries between patterns became blurred during the Wet Develop process.

On the other hand, in the case of Example 1, it was confirmed that a stable pattern was implemented even when DUV exposure was performed for 30 seconds (116 mJ/cm²) or longer, and in the case of Examples 2 and 3, it was confirmed that a stable pattern was implemented even at an exposure dose of 200 mJ/cm² or higher.

### [Experimental Example 3] Thermogravimetric Analysis (TGA)

Thermogravimetric analysis of the photoresist compositions of Examples 1 to 3 was performed.

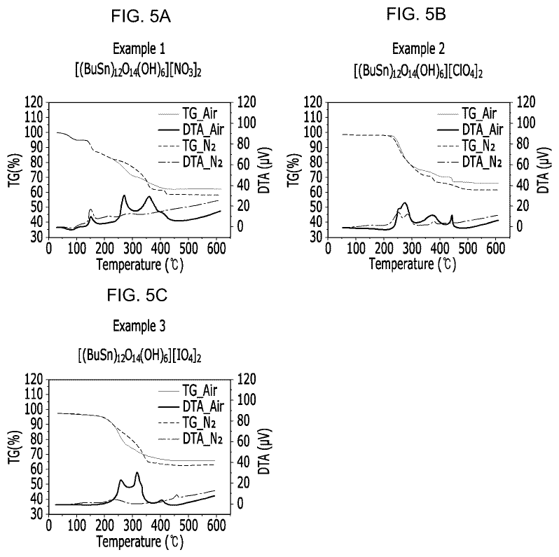

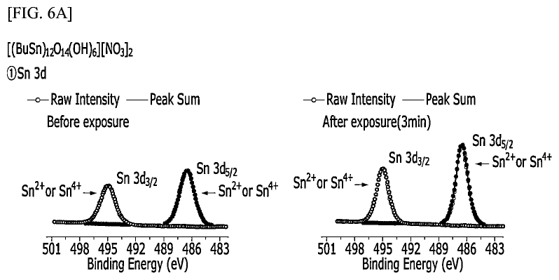

FIG. 5 is a thermogravimetric analysis (TGA) result of a photoresist composition according to Example of the present disclosure.

Referring to FIG. 5, it can be seen that each photoresist composition shows a weight change through an exothermic reaction at around 200° C., and in the case of Example 1, there is a weight change at around 150° C. Through this, it can be seen that the bonds of the elements constituting the photoresist are decomposed to form radicals, and at this time, a weight change occurs due to the loss of butyl groups, hydroxyl groups, and anions that have been bonded within the structure.

### [Experimental Example 4] X-Ray Photoelectron Spectroscopy

X-ray photoelectron spectroscopy (XPS) was performed on the photoresist compositions of Examples 1 to 3 before/after DUV exposure.

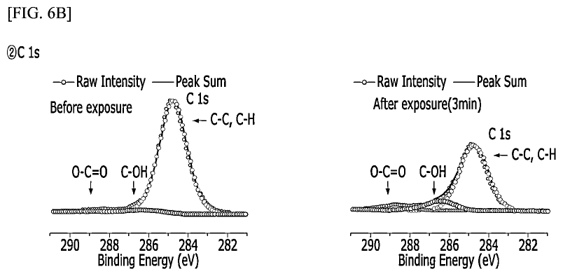

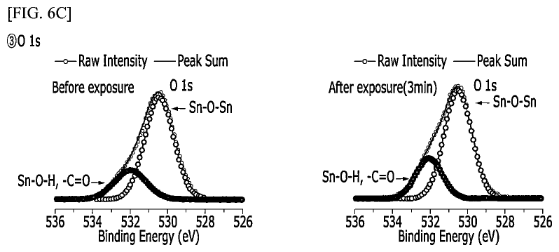

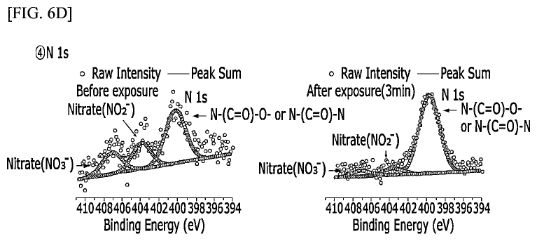

FIG. 6 is an X-ray photoelectron spectroscopy (XPS) result of a photoresist composition before/after DUV exposure according to Example 1 of the present disclosure.

Referring to FIG. 6A, it can be confirmed that when performing Sn 3d analysis of the thin film before DUV exposure, an Oxidized Sn Peak exists due to a Tin oxide network constituting the photoresist (located at 486.6 eV for Sn 3d5/2 and 495 eV for Sn 3d3/2), and it can be seen that after DUV irradiation, a photoreaction occurs and then the bond of the butyl group which has been bonded to Sn is broken, and thus the intensity of Sn increases.

Referring to FIG. 6B, in the C Is analysis, before exposure, the butyl group is stably bonded to Sn, and thus C—C and C—H peaks (284.8 eV) may be shown, and due to air exposure that inevitably occurs during spin coating or developing, O—C═O and C—OH bonds are shown at 288.6 eV and 286.5 eV, respectively. After exposure, due to the loss of butyl groups, the C—C and C—H peak intensities decrease, and the O—C═O and C—OH bonds increase.

Referring to FIG. 6C, in the case of O 1s, before exposure, Sn—O—Sn and Sn—O—H peaks derived from a Tin-oxo cluster structure may be observed at 530.4 eV and 532 eV and some O—C═O and C—OH contaminations may be included at 532 eV. As an O 1s analysis result after exposure, it can be seen that a Sn—O—Sn Peak slightly decreases, while a Sn—O—H Peak increases, which indicates that the Sn—O—H bonds decreased, but the O—C═O and C—OH bonds increased due to the photoreaction, resulting in an increase in intensity.

Referring to FIG. 6D, as an N Is analysis result before exposure, it can be seen that an N—(C═O)—O— or N—(C═O)—N peak, which is enabled due to bonds with nitrate (NO₃⁻), nitrite (NO₂⁻), and C═O, may be identified at positions of 407.1 eV, 403.9 eV, and 400.2 eV. However, when the exposure progresses, the decomposition of the nitrate ion, which is a radical reaction derivative, occurs to form radicals, and as a result, it can be seen that the intensities of nitrate and nitrite peaks decrease, and the intensities of N—(C═O)—O— and N—(C═O)—N peaks increase.

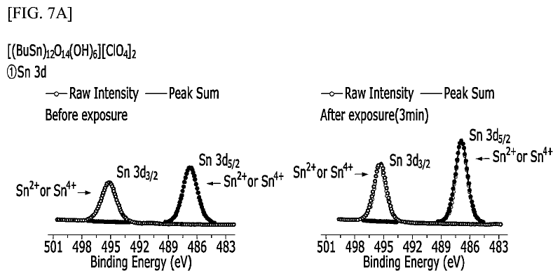

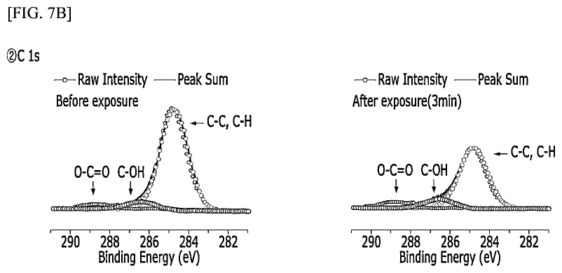

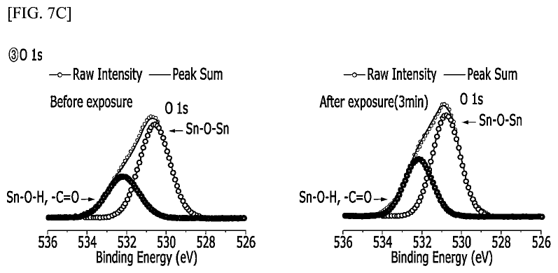

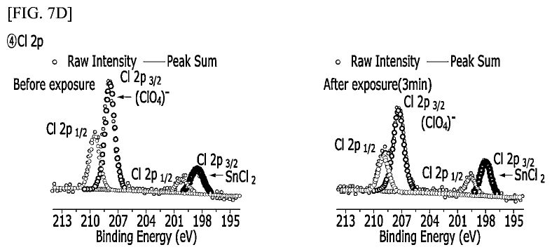

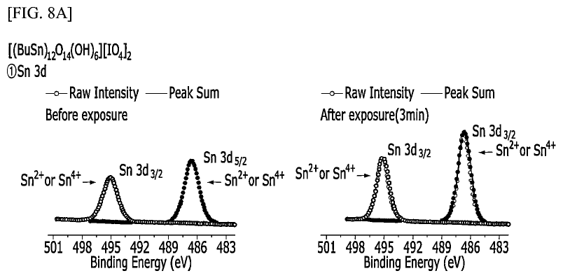

FIG. 7 is an X-ray photoelectron spectroscopy (XPS) result of a photoresist composition before/after DUV exposure according to Example 2 of the present disclosure.

Referring to FIG. 7A, it can be confirmed that when performing Sn 3d analysis before DUV exposure, an Oxidized Sn Peak exists due to a Tin oxide network by the same tendency as other photoresists (located at 486.8 eV for Sn 3d5/2 and 495.2 eV for Sn 3d3/2), and it can be seen that after DUV irradiation, the bond of the butyl group which has been bonded to Sn is broken by the photoreaction, and thus the intensity of Sn 3d increases.

Referring to FIG. 7B, during C 1s analysis, the butyl group is stably bonded to Sn before exposure and thus the C—C and C—H peaks (284.8 eV) may be shown, and O—C═O (288.6 eV) and C—OH (286.4 eV) contaminations are confirmed due to air exposure. It can be seen that after exposure, due to the loss of butyl groups, the C—C and C—H peak intensities decrease, and the O—C═O and C—OH bonds increase.

Referring to FIG. 7C, in the case of O 1s, Sn—O—Sn and Sn—O—H peaks derived from the Tin-oxo cluster structure may be observed at 530.6 eV and 532.1 eV before exposure. In the case of O 1s after exposure, it can be seen that the Sn—O—Sn peak intensity is almost similar, while the Sn—O—H bonds decrease due to the photoreaction, but the intensity increases due to the generation of O—C═O and C—OH bonds.

Referring to FIG. 7D, as a Cl 2p analysis result, it can be seen that Cl 2p3/2 has a ClO₄⁻ peak at 207.9 eV and Cl 2p1/2 has a ClO₄⁻ peak at 209.5 eV before/after exposure. Comparing before/after DUV, it can be seen that the intensity after DUV decreases by decomposition of ClO₄⁻ due to exposure. In addition, Cl 2p3/2 has metal chloride, i.e., SnCl₂ peak at 198.9 eV, and Cl 2p1/2 has metal chloride, i.e., SnCl₂ peak at 200.5 eV. It can be seen that the SnCl₂ peak intensity after DUV has increased due to an increase in SnCl₂ bonds caused by the decomposition of a chlorate ion, which is a radical reaction derivative after exposure.

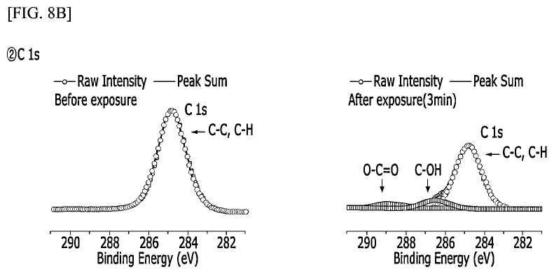

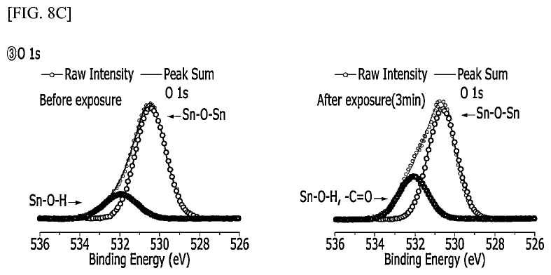

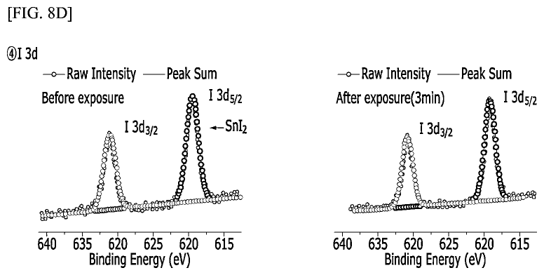

FIG. 8 is an X-ray photoelectron spectroscopy (XPS) result of a photoresist composition before/after DUV exposure according to Example 3 of the present disclosure.

Referring to FIG. 8A, it can be confirmed that when performing Sn 3d analysis of the thin film before DUV exposure, an Oxidized Sn Peak exists due to a Tin oxide network constituting the photoresist (located at 486.7 eV for Sn 3d5/2 and 495.1 eV for Sn 3d3/2) by the same tendency as Example 1, and it can be seen that even after DUV irradiation, a photoreaction occurs like [(BuSn)₁₂O₁₄(OH)₆][NO₃]₂ and then the bond of the butyl group which has been bonded to Sn is broken, and thus the intensity of Sn 3d increases.

Referring to FIG. 8B, during C 1s analysis, the butyl group is stably bonded to Sn before exposure and thus the C—C and C—H peaks (284.8 eV) may be shown, and O—C═O and C—OH contaminations are not confirmed due to air exposure. It can be seen that after exposure, due to the loss of butyl groups, the C—C and C—H peak intensities decrease, and O—C═O (288.8 eV) and C—OH (286.5 eV) bonds increase.

Referring to FIG. 8C, in the case of O 1s, Sn—O—Sn and Sn—O—H peaks derived from the Tin-oxo cluster structure may be observed at 530.4 eV and 531.9 eV before exposure. As an O 1s analysis result after exposure, it can be seen that an Sn—O—Sn Peak slightly decreases, while an Sn—O—H Peak increases, which indicates that due to the photoreaction, the Sn—O—H bonds decreased, but the O—C═O and C—OH bonds were generated, resulting in an increase in intensity.

Referring to FIG. 8D, as an I 3d analysis result, it can be seen that I 3d5/2 is located at 619.72 eV and I 3d3/2 is located at 631.22 eV before/after exposure, which is confirmed to be metal iodide, i.e., SnI₂ Peak. After exposure, the intensity of the I 3d Peak tends to decrease slightly.

### [Experimental Example 5] 13.5 nm EUV Exposure and Micropatterning Experiments

An experiment was performed to confirm the possibility of patterning, the stability of the implemented pattern, and the degree of surface roughness after Wet Develop by partially irradiating light through a Metal Mask during EUV exposure of 13.5 nm generated from a synchrotron accelerator on the thin films prepared using the photoresist compositions according to Example 1 and Comparative Example.

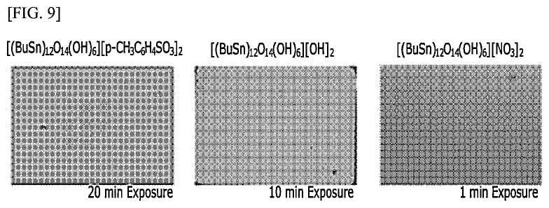

FIG. 9 is a micropattern formation result of a photoresist composition before/after EUV exposure according to Example 1 of the present disclosure.

Referring to FIG. 9, in the case of conventional Tosylate-based [(BuSn)₁₂O₁₄(OH)₆][p-CH₃C₆H₄SO₃]₂ as Comparative Example, it is well known that a large exposure dose is required, and even in the experiment, micro pattern formation was shown only in EUV exposure of at least 20 minutes, but in the case of [(BuSn)₁₂O₁₄(OH)₆][OH]₂, patterns were formed in exposure of 10 minutes or less. This is a similar characteristic to the results in existing literature. When [(BuSn)₁₂O₁₄(OH)₆][NO₃]₂ as Example 1 was applied to EUV PR, it was evaluated that significantly improved photosensitivity was achieved by showing the pattern formation even under an exposure condition of 1 minute.

The aforementioned description of the present disclosure is to be exemplified, and it will be understood by those skilled in the art that the present disclosure can be easily modified in other detailed forms without changing the technical spirit or required features of the present disclosure. Therefore, it should be appreciated that the embodiments described above are illustrative in all aspects and are not restricted. For example, each component described as single may be implemented in a distributed manner, and similarly, components described as distributed may also be implemented in a combined form.

The scope of the present disclosure is represented by appended claims to be described below rather than the detailed description. and it is to be interpreted that the meaning and scope of the claims and all the changes or modified forms derived from the equivalents thereof come within the scope of the present disclosure.

1. A photoresist composition comprising:
a tin-oxo cluster;
an oxidizing agent; and
a polar organic solvent
wherein when irradiated with ultraviolet, bonds constituting the cluster are broken to form cross-linking between the clusters

2. The photoresist composition of claim 1, wherein the tin-oxo cluster includes a compound represented by the following Chemical Formula 1:
[(BuSn)₁₂O₁₄(OH)₆][X]₂ [Chemical Formula 1]
(in Chemical Formula 1, X is p-CH₃C₆H₄SO₃ or OH).

3. The photoresist composition of claim 2, wherein the X is substituted with a radical reaction derivative by the oxidizing agent.

4. The photoresist composition of claim 3, wherein the radical reaction derivative includes anions selected from the group consisting of NO₃⁻, BrO₃⁻, ClO₄⁻, IO₄⁻, and combinations thereof.

5. The photoresist composition of claim 3, wherein photosensitivity of the photoresist composition is increased by the substitution.

6. The photoresist composition of claim 1, wherein the oxidizing agent includes an oxidizing agent selected from the group consisting of nitric acid, bromic acid, perchloric acid, periodic acid, and combinations thereof.

7. The photoresist composition of claim 1, wherein the polar organic solvent includes a solvent selected from the group consisting of methanol, ethanol, 2-propanol, 2-methoxyethanol, and combinations thereof.

8. A photolithography process comprising:
forming a thin film by coating the photoresist composition according to claim 1;
heat-treating the thin film;
irradiating ultraviolet after disposing a mask on the thin film; and
immersing the thin film in a solvent.

9. The photolithography process of claim 8, wherein the bonds constituting the cluster are broken by the irradiation to form cross-linking between the clusters.

10. The photolithography process of claim 8, wherein in the immersing of the thin film in the solvent, a portion of the thin film that is not irradiated with ultraviolet is dissolved in the solvent.

11. The photolithography process of claim 8, wherein the coating is performed by spin coating, bar coating, gravure printing, screen printing or ink-jet printing.

12. The photolithography process of claim 8, wherein the heat treatment is performed in a temperature range of 30° C. to 150° C.

13. The photolithography process of claim 8, wherein the solvent includes a solvent selected from the group consisting of ethanol, isopropyl alcohol, butanol, methyl ethyl ketone, dimethyl sulfoxide, and combinations thereof.

14. An EUV photoresist comprising the photoresist composition according to claim 1.
